(19) United States
(12) Patent Application Publication
(10) Pub. No.: US 2025/0159989 A1
(43) Pub. Date: May 15, 2025

(54) DISPLAY PANEL AND DISPLAY APPARATUS

(71) Applicants: HEFEI BOE DISPLAY TECHNOLOGY CO., LTD., Hefei, Anhui (CN); BOE TECHNOLOGY GROUP CO., LTD., Beijing (CN)

(72) Inventors: Qi LIU, Beijing (CN); Hui LI, Beijing (CN); Wei ZHANG, Beijing (CN); Jilei GAO, Beijing (CN)

(73) Assignees: HEFEI BOE DISPLAY TECHNOLOGY CO., LTD., Hefei, Anhui (CN); BOE TECHNOLOGY GROUP CO., LTD., Beijing (CN)

(21) Appl. No.: 18/837,013

(22) PCT Filed: Nov. 13, 2023
(86) PCT No.: PCT/CN2023/131236

§ 371 Date: Aug. 8, 2024

(30) Foreign Application Priority Data
Dec. 8, 2022 (WO) PCT/CN2022/137469
Jan. 6, 2023 (CN) 202310016843.X

(51) Int. Cl. H10D 86/40

(52) U.S. Cl. CPC H10D 86/441

(57) ABSTRACT

The present disclosure provides a display panel and a display apparatus. The display panel includes: a fan-out region including multiple fan-out wire portions, each fan-out wire portion including multiple wires, and the multiple wires including multiple first wire groups arranged along a direction from a middle position of each fan-out wire portion to a first boundary position of each fan-out wire portion. In the fan-out wire portions, the width of the wire closest to the first boundary position of at least one fan-out wire portion among the at least one fan-out wire portion is greater than the width of the wire closest to the first boundary position of another fan-out wire portion among the another fan-out wire portion.

### CROSS-REFERENCE TO RELATED APPLICATIONS

The present application is a U.S. National Stage Application under 35 U.S.C. § 371 of International Patent Application No. PCT/CN2023/131236, filed on Nov. 13, 2023, which is based on and claims priority to PCT International Application No. PCT/CN2022/137469 filed on Dec. 8, 2022 and China Patent Application No. 202310016843.X filed on Jan. 6, 2023, the disclosures of which are incorporated by reference herein in their entirety.

### TECHNICAL FIELD

The present disclosure relates to a display panel and a display apparatus.

### BACKGROUND

There have been great changes in the development of the television industry. From black-and-white television sets to color television sets, and now to large-screen smart television sets, the innovative technology of television sets is always in a state of flux. At present, LCD (Liquid Crystal Display) products are also more and more applied in television sets and other display products.

### SUMMARY

According to an aspect of the present disclosure, a display panel is provided. The display panel comprises: a fanout area comprising a plurality of fanout wire portions, wherein each fanout wire portion of the plurality of fanout wire portions comprises a plurality of wires, the plurality of wires comprising a plurality of first wire groups arranged along a direction from a middle position of the each fanout wire portion to a first boundary position of the each fanout wire portion, and in the plurality of fanout wire portions, a width of a wire closest to the first boundary position of at least one fanout wire portion in the at least one fanout wire portion being greater than a width of a wire closest to the first boundary position of another fanout wire portion in the another fanout wire portion.

In some embodiments, in the plurality of first wire groups of the each fanout wire portion, a difference between widths of adjacent wires in a first wire group close to the first boundary position of the each fanout wire portion is greater than a difference between widths of adjacent wires in a first wire group away from the first boundary position of the each fanout wire portion.

In some embodiments, the plurality of first wire groups comprise: a first sub-wire group close to the first boundary position of the each fanout wire portion and a second sub-wire group close to the middle position of the each fanout wire portion, wherein a difference between widths of adjacent wires in the first sub-wire group is greater than a difference between widths of adjacent wires in the second sub-wire group.

In some embodiments, the plurality of first wire groups further comprise a third sub-wire group between the first sub-wire group and the second sub-wire group, wherein a difference between widths of adjacent wires in the third sub-wire group is less than the difference between the widths of the adjacent wires in the first sub-wire group, and the difference between the widths of the adjacent wires in the third sub-wire group is greater than the difference between the widths of the adjacent wires in the second sub-wire group.

In some embodiments, the difference between the widths of the adjacent wires in the first sub-wire group ranges from 6.25 nanometers to 10.42 nanometers; and the difference between the widths of the adjacent wires in the second sub-wire group ranges from 4.17 nanometers to 8.33 nanometers.

In some embodiments, the difference between the widths of the adjacent wires in the first sub-wire group ranges from 6.25 nanometers to 10.42 nanometers; the difference between the widths of the adjacent wires in the second sub-wire group ranges from 4.17 nanometers to 8.33 nanometers; and the difference between the widths of the adjacent wires in the third sub-wire group ranges from 5.21 nanometers to 9.38 nanometers.

In some embodiments, for a wire in each first wire group of the plurality of first wire groups, the closer to the first boundary position of the each fanout wire portion, the greater a width of the wire.

In some embodiments, a difference between widths of adjacent wires in the each first wire group is equal.

In some embodiments, the each fanout wire portion further comprises a plurality of leads, wherein the plurality of leads are connected to the plurality of wires in one-to-one correspondence, and a width of each wire of the plurality of wires is equal to a width of a lead connected with the each wire.

In some embodiments, the each fanout wire portion further comprises a plurality of leads, wherein the plurality of leads are connected to the plurality of wires in one-to-one correspondence, widths of the plurality of leads are equal, and the widths of the plurality of leads are all equal to a width of a wire at the middle position of the each fanout wire portion.

In some embodiments, the plurality of wires further comprise a plurality of second wire groups arranged along a direction from the middle position of the each fanout wire portion to a second boundary position of the each fanout wire portion, wherein the second boundary position is opposite to the first boundary position, and in the plurality of fanout wire portions, a width of a wire closest to the second boundary position of at least one fanout wire portion in the at least one fanout wire portion is greater than a width of a wire closest to the second boundary position of another fanout wire portion in the another fanout wire portion.

In some embodiments, in the plurality of second wire groups of the each fanout wire portion, a difference between widths of adjacent wires in a second wire group close to the second boundary position of the each fanout wire portion is greater than a difference between widths of adjacent wires in a second wire group away from the second boundary position of the each fanout wire portion.

In some embodiments, the plurality of second wire groups comprise: a fourth sub-wire group close to the second boundary position of the each fanout wire portion and a fifth sub-wire group close to the middle position of the each fanout wire portion, wherein a difference between widths of adjacent wires in the fourth sub-wire group is greater than a difference between widths of adjacent wires in the fifth sub-wire group.

In some embodiments, the plurality of second wire groups further comprise a sixth sub-wire group between the fourth sub-wire group and the fifth sub-wire group, wherein a difference between widths of adjacent wires in the sixth sub-wire group is less than the difference between the widths of the adjacent wires in the fourth sub-wire group, and the difference between the widths of the adjacent wires in the sixth sub-wire group is greater than the difference between the widths of the adjacent wires in the fifth sub-wire group.

In some embodiments, for a wire in each second wire group of the plurality of second wire groups, the closer to the second boundary position of the each fanout wire portion, the greater a width of the wire.

In some embodiments, a difference between widths of adjacent wires in the each second wire group is equal.

In some embodiments, a difference between widths of adjacent wires in each first wire group of the plurality of first wire groups of the each fanout wire portion is equal, the difference is not 0, and a width of a fanout wire in the each first wire group is positively correlated with a distance from the fanout wire to the middle position of the each fanout wire portion; and the plurality of first wire groups comprise: a first sub-wire group close to the first boundary position of the each fanout wire portion and a second sub-wire group adjacent to the first sub-wire group and close to the middle position of the each fanout wire portion, wherein a width of the fanout wire closest to the second sub-wire group in the first sub-wire group is equal to a width of the fanout wire closest to the first sub-wire group in the second sub-wire group.

In some embodiments, the plurality of wires further comprise a plurality of second wire groups arranged along a direction from the middle position of the each fanout wire portion to a second boundary position of the each fanout wire portion, wherein the second boundary position is opposite to the first boundary position; a difference between widths of adjacent wires in each second wire group of the plurality of second wire groups of the each fanout wire portion is equal, the difference is not 0, and a width of a fanout wire in the each second wire group is positively correlated with a distance from the fanout wire to the middle position of the each fanout wire portion; and the plurality of second wire groups comprise a fourth sub-wire group close to the second boundary position of the each fanout wire portion and a fifth sub-wire group adjacent to the fourth sub-wire group and close to the middle position of the each fanout wire portion, wherein a width of the fanout wire closest to the fifth sub-wire group in the fourth sub-wire group is equal to a width of the fanout wire closest to the fourth sub-wire group in the fifth sub-wire group.

In some embodiments, in each fanout wire portion of the at least one fanout wire portion, the plurality of second wire groups and the plurality of first wire groups are symmetrically arranged according to the width of the fanout wire.

In some embodiments, in each fanout wire portion of the at least one fanout wire portion, a width of the fanout wire closest to the second boundary position is greater than a width of the fanout wire closest to the first boundary position.

In some embodiments, the each fanout wire portion further comprises a plurality of leads, wherein the plurality of leads are electrically connected to the plurality of wires in one-to-one correspondence, widths of the plurality of leads are equal, a width of each lead of the plurality of leads is less than or equal to a width of a wire electrically connected to the each lead, and a distance between adjacent leads in the plurality of leads is equal.

In some embodiments, in the fanout area, the width of a lead in one fanout wire portion is greater than the width of a lead in another fanout wire portion, and the distance between adjacent leads in the one fanout wire portion is less than the distance between adjacent leads in the another fanout wire portion.

In some embodiments, in the plurality of first wire groups of the each fanout wire portion, a number of a fanout wire of each of other first wire groups than a first wire group closest to the first boundary position is equal, and in the plurality of second wire groups of the each fanout wire portion, a number of a fanout wire of each of other second wire groups than a second wire group closest to the second boundary position is equal, and the number of the fanout wire of the each of the other second wire groups is equal to the number of the fanout wire of the each of the other first wire groups.

In some embodiments, in each of the at least one fanout wire portion, a width of a fanout wire closest to the first boundary position is greater than a width of a fanout wire closest to the second boundary position.

In some embodiments, the number of the fanout wire of the each of the other first wire groups ranges from 3 to 5, and the number of the fanout wire of the each of the other second wire groups ranges from 3 to 5.

In some embodiments, in the plurality of fanout wire portions, a difference between widths of adjacent wires of adjacent fanout wire portions close to a boundary position of the fanout area is greater than or equal to a difference between widths of adjacent wires of adjacent fanout wire portions close to a middle position of the fanout area.

In some embodiments, the adjacent fanout wire portions close to the boundary position of the fanout area comprise: a first fanout wire portion close to the boundary position of the fanout area, and a second fanout wire portion on a side of the first fanout wire portion away from the boundary position of the fanout area and adjacent to the first fanout wire portion, wherein the first fanout wire portion comprises a first wire, the first wire being a wire closest to the second fanout wire portion in the first fanout wire portion, and the second fanout wire portion comprises a second wire, the second wire being a wire closest to the first fanout wire portion in the second fanout wire portion, wherein the first wire and the second wire are the adjacent wires of the adjacent fanout wire portions close to the boundary position of the fanout area; the adjacent fanout wire portions close to the middle position of the fanout area comprise: a third fanout wire portion and a fourth fanout wire portion which are close to the middle position of the fanout area, wherein the third fanout wire portion comprises a third wire, the third wire being a wire closest to the fourth fanout wire portion in the third fanout wire portion, and the fourth fanout wire portion comprises a fourth wire, the fourth wire being a wire closest to the third fanout wire portion in the fourth fanout wire portion, wherein the third wire and the fourth wire are the adjacent wires of the adjacent fanout wire portions close to the middle position of the fanout area; and a difference between a width of the first wire and a width of the second wire is greater than or equal to a difference between a width of the third wire and a width of the fourth wire.

In some embodiments, the difference between the widths of the adjacent wires of the adjacent fanout wire portions ranges from 0.05 microns to 0.2 microns.

In some embodiments, the display panel further comprises: a display area; and a gate driving circuit electrically connected to the display area, wherein the display area and the gate driving circuit are electrically connected to the plurality of fanout wire portions.

In some embodiments, the display panel further comprises: a plurality of chips on film (COFs) electrically connected to the plurality of fanout wire portions in one-to-one correspondence, and located on a side of the plurality of fanout wire portions away from the display area.

According to another aspect of the present disclosure, a display panel is provided. The display panel comprises: a fanout area comprising a plurality of fanout wire portions, wherein each fanout wire portion of the plurality of fanout wire portions comprises a plurality of wires and a plurality of leads, wherein the plurality of wires comprise a part of wires arranged along a direction from a middle position of the each fanout wire portion to a first boundary position of the each fanout wire portion, and a difference between a width of a wire close to the first boundary position in the part of wires and a width of a lead connected to the wire close to the first boundary position is greater than or equal to a difference between a width of a wire away from the first boundary position in the part of wires and a width of a lead connected to the wire away from the first boundary position.

In some embodiments, the part of wires comprise a plurality of first wire groups arranged along the direction from the middle position of the each fanout wire portion to the first boundary position of the each fanout wire portion, wherein the plurality of first wire groups comprise: a first sub-wire group close to the first boundary position of the each fanout wire portion and a second sub-wire group close to the middle position of the each fanout wire portion, wherein a difference between a width of a wire of the first sub-wire group and a width of a lead connected to the wire of the first sub-wire group is greater than or equal to a difference between a width of a wire of the second sub-wire group and a width of a lead connected to the wire of the second sub-wire group.

In some embodiments, the plurality of wires comprise: a first fanout wire at the first boundary position of the each fanout wire portion; a second fanout wire adjacent to the first fanout wire; and a third fanout wire on a side of the second fanout wire away from the first fanout wire and adjacent to the second fanout wire; wherein a width of the first fanout wire is greater than a width of the second fanout wire, and the width of the second fanout wire is equal to a width of the third fanout wire.

In some embodiments, a difference between the width of the first fanout wire and the width of the second fanout wire is 0.01 microns.

According to another aspect of the present disclosure, a display apparatus is provided. The display apparatus comprises the display panel as described previously.

Other features and advantages of the present disclosure will become clear from the following detailed description of exemplary embodiments of the present disclosure with reference to the accompanying drawings.

### BRIEF DESCRIPTION OF THE DRAWINGS

The accompanying drawings which constitute part of this specification, describe the embodiments of the present disclosure, and together with this serve to explain the principles of the present disclosure.

The present disclosure may be more explicitly understood from the following detailed description with reference to the accompanying drawings, in which:

FIG. 1A is a schematic view schematically showing a pixel arrangement of a display panel according to an embodiment in the related art;

FIG. 1B is a schematic view schematically showing a pixel arrangement of a display panel according to another embodiment in the related art;

FIG. 1C is a schematic view schematically showing a pixel arrangement of a display panel according to another embodiment in the related art;

FIG. 2A is a schematic wiring view schematically showing a fanout area of a display panel according to an embodiment in the related art;

FIG. 2B is a schematic wiring view schematically showing a fanout area of a display panel according to another embodiment in the related art;

FIG. 2C is a schematic wiring view schematically showing a fanout area of a display panel according to another embodiment in the related art;

FIG. 3 is a schematic view showing a display panel according to an embodiment of the present disclosure;

FIG. 4 is a schematic view showing a display panel according to another embodiment of the present disclosure;

FIG. 5 is a schematic view showing a display panel according to another embodiment of the present disclosure;

FIG. 6 is a schematic view showing a display panel according to another embodiment of the present disclosure;

FIG. 7 is a schematic view showing a display panel according to another embodiment of the present disclosure;

FIG. 8 is a schematic view showing a fanout wire and a lead of a fanout wire portion according to an embodiment of the present disclosure;

FIG. 9 is a schematic view showing a display panel according to another embodiment of the present disclosure.

It should be understood that the dimensions of various parts shown in the accompanying drawings are not necessarily drawn according to actual proportional relations. In addition, the same or similar components are denoted by the same or similar reference signs.

### DETAILED DESCRIPTION

Various exemplary embodiments of the present disclosure will now be described in detail in conjunction with the accompanying drawings. The description of the exemplary embodiments is merely illustrative and is in no way intended as a limitation to the present disclosure, its application or use. The present disclosure may be implemented in many different forms, which are not limited to the embodiments described herein. These embodiments are provided to make the present disclosure thorough and complete, and fully convey the scope of the present disclosure to those skilled in the art. It should be noticed that: relative arrangement of components and steps, material composition, numerical expressions, and numerical values set forth in these embodiments, unless specifically stated otherwise, should be explained as merely illustrative, and not as a limitation.

The use of the terms “first”, “second” and similar words in the present disclosure do not denote any order, quantity or importance, but are merely used to distinguish between different parts. A word such as “comprise”, “include”, or the like means that the element before the word covers the element(s) listed after the word without excluding the possibility of also covering other elements. The terms “up”, “down”, “left”, “right”, or the like are used only to represent a relative positional relationship, and the relative positional relationship may be changed correspondingly if the absolute position of the described object changes.

In the present disclosure, when it is described that a particular device is located between the first device and the second device, there may be an intermediate device between the particular device and the first device or the second device, and alternatively, there may be no intermediate device. When it is described that a particular device is connected to other devices, the particular device may be directly connected to said other devices without an intermediate device, and alternatively, may not be directly connected to said other devices but with an intermediate device.

All the terms (comprising technical and scientific terms) used in the present disclosure have the same meanings as understood by those skilled in the art of the present disclosure unless otherwise defined. It should also be understood that terms as defined in general dictionaries, unless explicitly defined herein, should be interpreted as having meanings that are consistent with their meanings in the context of the relevant art, and not to be interpreted in an idealized or extremely formalized sense.

Techniques, methods, and apparatus known to those of ordinary skill in the relevant art may not be discussed in detail, but where appropriate, these techniques, methods, and apparatuses should be considered as part of this specification.

In the design of the display product in the related art, GOA (Gate on Array, which may also be a gate driving circuit) may be arranged on a short side of the display panel, and COF (Chip On Film) may be bound on a long side of the display panel.

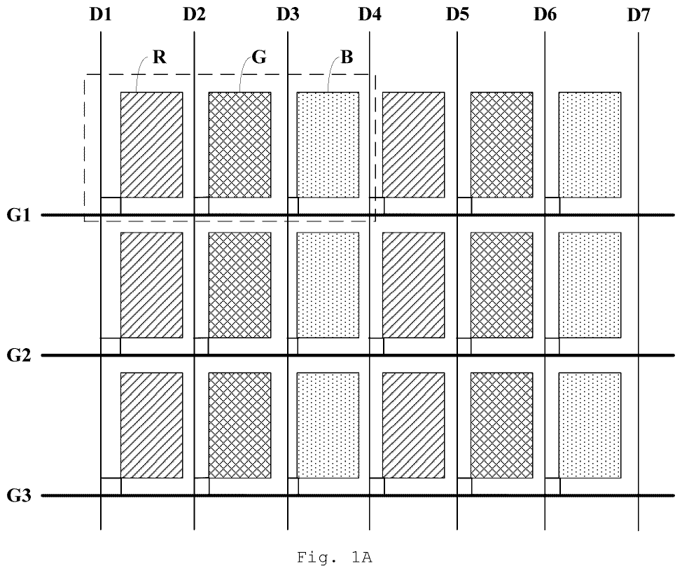

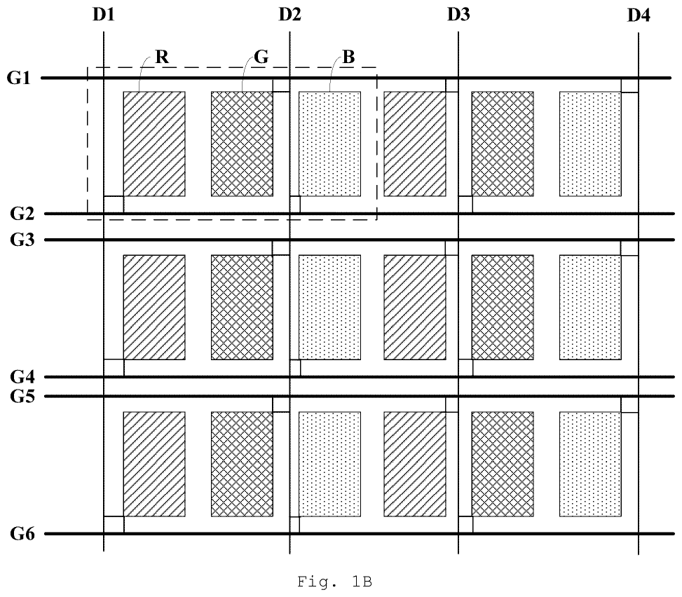

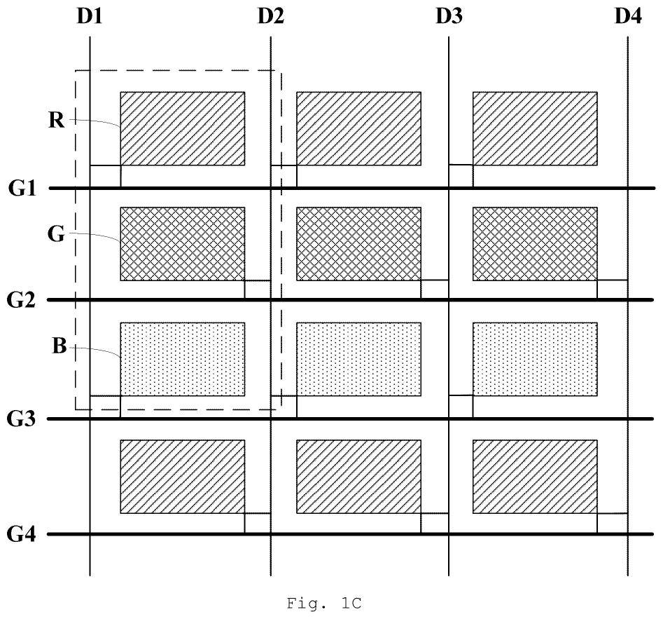

FIGS. 1A to 1C are schematic views schematically showing a pixel arrangement of a display panel according to several embodiments in the related art.

FIG. 1A is a schematic view of a pixel arrangement of a display panel with a single gate line in the related art. Data lines D1 to D7 and gate lines G1 to G3 are shown in FIG. 1A, and each pixel may comprise a red sub-pixel R, a green sub-pixel G, and a blue sub-pixel B. As shown in FIG. 1A, one pixel is electrically connected to one gate line.

FIG. 1B is a schematic view of a pixel arrangement of a display panel with dual gate lines in the related art. Data lines D1 to D4 and gate lines G1 to G6 are shown in FIG. 1B, and each pixel may comprise a red sub-pixel R, a green sub-pixel G, and a blue sub-pixel B. As may be seen from FIG. 1B, one pixel is electrically connected to two gate lines, so that the number of gate lines of a display panel with dual gate lines is twice the number of gate lines of a display panel with a single gate line.

FIG. 1C is a schematic view of a pixel arrangement of a display panel with triple gate lines in the related art. Data lines D1 to D4 and gate lines G1 to G4 are shown in FIG. 1C, and each pixel may comprise a red sub-pixel R, a green sub-pixel G, and a blue sub-pixel B. As may be seen from FIG. 1C, one pixel is electrically connected to three gate lines, so that the number of gate lines of a display panel with triple gate lines is three times the number of gate lines of a display panel with a single gate line.

In addition, as shown in FIG. 1A, in a display panel with a single gate line, one pixel is electrically connected to three data lines. As shown in FIG. 1B, in a display panel with dual gate lines, one pixel is electrically connected to 1.5 data lines. As shown in FIG. 1C, in a display panel with triple gate lines, one pixel is electrically connected to one data line. In this way, the number of data lines of a display panel with dual gate lines is half the number of data lines of a display panel with a single gate line, and the number of data lines of a display panel with triple gate lines is one third the number of data lines of a display panel with a single gate line. Since the data line is electrically connected to COF through a fanout area, the number of COFs of a display panel with dual gate lines may be reduced to half the number of data lines of a display panel with a single gate line, and the number of COFs of a display panel with triple gate lines may be reduced to one third the number of data lines of a display panel with a single gate line.

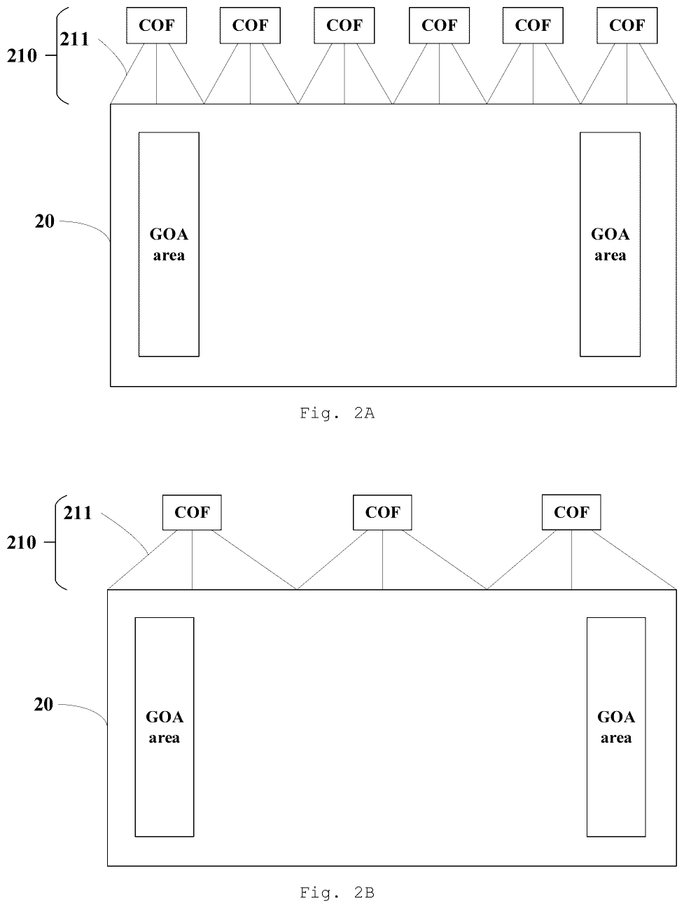

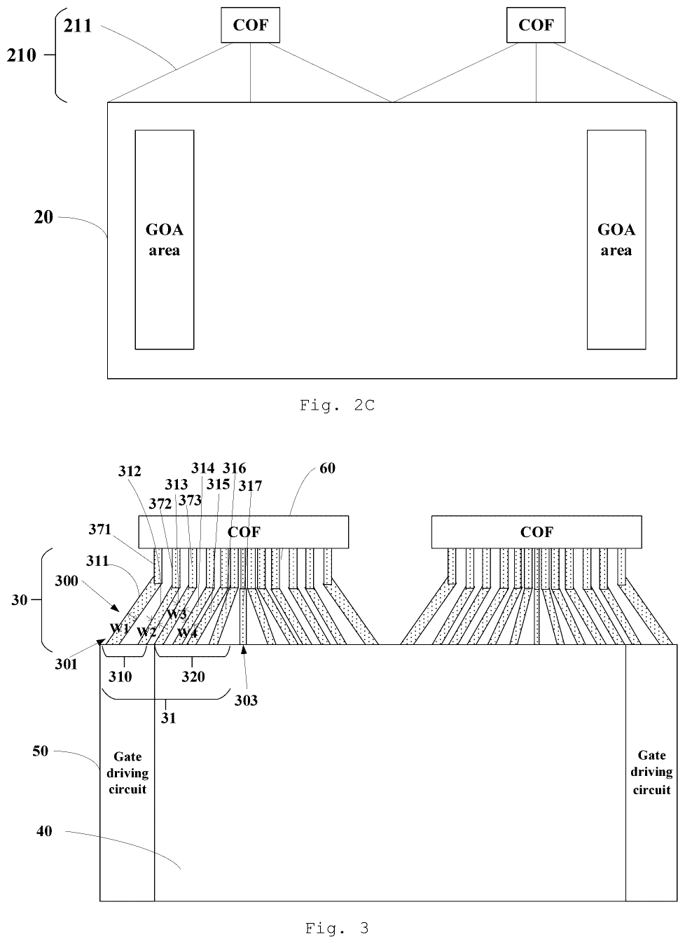

FIGS. 2A to 2C are schematic wiring views schematically showing a fanout area of a display panel according to several embodiments in the related art.

The display panel shown in FIG. 2A is a display panel corresponding to the pixel arrangement shown in FIG. 1A, that is, a display panel with a single gate line. The display panel shown in FIG. 2B is a display panel corresponding to the pixel arrangement shown in FIG. 1B, that is, a display panel with dual gate lines. The display panel shown in FIG. 2C is a display panel corresponding to the pixel arrangement shown in FIG. 1C, that is, a display panel with triple gate lines.

FIGS. 2A to 2C show a display panel 20 comprising a GOA area, a fanout area 210 and a plurality of COFs, wherein the fanout area 210 comprises a plurality of fanout wires 211.

As may be seen from FIGS. 2A and 2B, the number of COFs used in a display panel with dual gate lines is half the number of COFs used in a display panel with a single gate line. As may be seen from FIG. 2A and FIG. 2C, the number of COFs used in a display panel with triple gate lines is one third the number of COFs used in a display panel with a single gate line.

As described previously, the number of gate lines of a display panel with triple gate lines is three times the number of gate lines of a display panel with a single gate line. In a display panel with triple gate lines, with an increased number of gate lines, there is a relatively large parasitic capacitance between the gate line and the common electrode line, so that this design has a great influence on the voltage of the common electrode line, which might result in a drop in a charging rate.

The inventors of the present disclosure have found that, there is a large resistance difference between the fanout wires electrically connected to the same COF in the display panel, which might result in a difference in a charging rate in different areas, and might further lead to the problem of poor display. For example, the closer to the boundary of the fanout wire portion, the greater the length of the fanout wire, which results in the greater resistance of the fanout wire, and the more obvious increase in resistance. For example, in the related art, in the fanout wire portion connected to the same COF, the resistance of the fanout wire at a boundary position of the fanout wire portion is 25Ω (Ohm) to 45Ω greater than the resistance of the fanout wire at the middle position of the fanout wire portion.

In view of this, the embodiment of the present disclosure provides a display panel to reduce a resistance difference between various fanout wires of the display panel. The display panel will be described in detail in conjunction with the accompanying drawings.

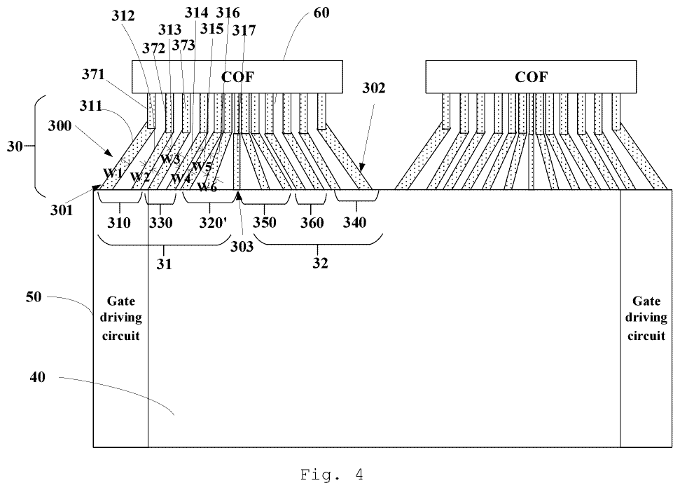

FIG. 3 is a schematic view showing a display panel according to an embodiment of the present disclosure.

As shown in FIG. 3, the display panel comprises a fanout area 30. The fanout area 30 comprises a plurality of fanout wire portions 300. Here, each fanout wire portion is a group of fanout wires electrically connected to a same COF 60. Each fanout wire portion 300 comprises a plurality of wires. The plurality of wires comprise a plurality of first wire groups 31 arranged along a direction from a middle position 303 of the each fanout wire portion to a first boundary position 301 of the each fanout wire portion. In the plurality of fanout wire portions, a width of a wire closest to the first boundary position of at least one fanout wire portion in the at least one fanout wire portion is greater than a width of a wire closest to the first boundary position of another fanout wire portion in the another fanout wire portion.

So far, a display panel according to an embodiment of the present disclosure is provided. The display panel comprises: a fanout area comprising a plurality of fanout wire portions, wherein each fanout wire portion of the plurality of fanout wire portions comprises a plurality of wires, the plurality of wires comprising a plurality of first wire groups arranged along a direction from a middle position of the each fanout wire portion to a first boundary position of the each fanout wire portion, and in the plurality of fanout wire portions, a width of a wire closest to the first boundary position of at least one fanout wire portion in the at least one fanout wire portion being greater than a width of a wire closest to the first boundary position of another fanout wire portion in the another fanout wire portion. This can reduce a resistance difference between the fanout wires of the display panel as much as possible and improve the display effect of the display panel.

In some embodiments, in the plurality of first wire groups 31 of the each fanout wire portion, a difference between widths of adjacent wires in a first wire group close to the first boundary position 301 of the each fanout wire portion is greater than a difference between widths of adjacent wires in a first wire group away from the first boundary position 301 of the each fanout wire portion (for example, a first wire group close to the middle position 303). The closer to the first boundary position of the fanout wire portion, the greater the difference between the widths of adjacent wires in the first wire group, so that it is possible to reduce a resistance difference between the fanout wires of the display panel as much as possible and further improve the display effect of the display panel.

For example, as shown in FIG. 3, the plurality of first wire groups 31 in each fanout wire portion 300 comprise: a first sub-wire group 310 close to the first boundary position 301 of the each fanout wire portion and a second sub-wire group 320 close to the middle position 303 of the each fanout wire portion. A difference between widths of adjacent wires in the first sub-wire group 310 is greater than a difference between widths of adjacent wires in the second sub-wire group 320.

For example, as shown in FIG. 3, the first sub-wire group 310 comprises a first fanout wire 311 and a second fanout wire 312, and the second sub-wire group 320 comprises a third fanout wire 313, a fourth fanout wire 314, a fifth fanout wire 315 and a sixth fanout wire 316. A width of the first fanout wire 311 is a first width W1, a width of the second fanout wire 312 is a second width W2, a width of the third fanout wire 313 is a third width W3, and a width of the fourth fanout wire 314 is a fourth width W4. Here, a width of each fanout wire is a dimension of the each fanout wire perpendicular to an extension direction (also that is, a length direction) of the each fanout wire. In addition, FIG. 3 also shows a fanout wire located at the middle position 303 of the fanout wire portion, that is, a seventh fanout wire 317.

It is to be noted that, when the difference between the widths of adjacent wires of a certain sub-wire group is calculated, a difference between a width of a certain fanout wire in the sub-wire group and a width of a fanout wire closest to the certain fanout wire in the sub-wire group can be calculated.

For example, the first sub-wire group 310 comprises a first fanout wire 311 and a second fanout wire 312, so that a difference between the width of the first fanout wire 311 and the width of the second fanout wire 312 adjacent to the first fanout wire 311 (i.e., a difference between the first width W1 and the second width W2) may be used as the difference between the widths of adjacent wires in the first sub-wire group 310.

For another example, the second sub-wire group 320 comprises a plurality of fanout wires, so that a difference between the width of the third fanout wire 313 and the width of the fourth fanout wire 314 adjacent to the third fanout wire 313 (that is, a difference between the third width W3 and the fourth width W4) may be used as the difference between the widths of adjacent wires in the second sub-wire group 320.

In the above-described embodiments, the difference between the first width W1 and the second width W2 is greater than the difference between the third width W3 and the fourth width W4.

For example, the difference between the widths of adjacent wires in the first sub-wire group 310 ranges from 6.25 nanometers to 10.42 nanometers. For another example, the difference between the widths of adjacent wires in the second sub-wire group ranges from 4.17 nanometers to 8.33 nanometers.

It is to be noted that, although the fanout area shown in FIG. 3 comprises two fanout wire portions 300, the scope of the present disclosure is not limited thereto. For example, the fanout area may comprise more than two fanout wire portions.

In some embodiments, for a wire in each first wire group of the plurality of first wire groups, the closer to the first boundary position of the each fanout wire portion, the greater a width of the wire. For example, in the second sub-wire group 320, the closer the fanout is to the first boundary position 301, the greater the width of the fanout wire is. For example, W2>W3>W4. This can reduce a resistance difference between the wires in each first wire group.

In some embodiments, a difference between widths of adjacent wires in the each first wire group is equal.

For example, the above-described difference is a value other than 0, so that the widths of a plurality of wires in each first wire group increase uniformly along a direction from the middle position of the fanout wire portion to the first boundary position of the fanout wire portion. In this way, for the first wire group comprising fanout wires with a relatively large length difference, a resistance difference between the fanout wires in the first wire group can be made relatively small.

For another example, the above-described difference is 0, so that the widths of the plurality of wires in each first wire group are equal. In this way, for the first wire group comprising fanout wires with a relatively small length difference, a resistance difference between the fanout wires in the first wire group can be made relatively small. For example, a resistance of each fanout wire in a same fanout wire portion can be made uniform, so as to avoid a difference in a charging rate of each fanout wire as much as possible.

In some embodiments, as shown in FIG. 3, the display panel further comprises a display area 40 and a gate driving circuit 50 electrically connected to the display area 40. The display area 40 and the gate driving circuit 50 are electrically connected to the plurality of fanout wire portions.

In some embodiments, as shown in FIG. 3, the display panel further comprises a plurality of COFs 60. The plurality of COFs 60 are electrically connected to the plurality of fanout wire portions 300 in one-to-one correspondence, and located on a side of the plurality of fanout wire portions away from the display area 40. That is, the plurality of COFs 60 are electrically connected to the display area 40 (for example, a data line in the display area 40) and the gate driving circuit 50 through the plurality of fanout wire portions 300 of the fanout area 30.

In some embodiments, as shown in FIG. 3, each fanout wire portion 300 further comprises a plurality of leads (for example, leads 371, 372 and 373, etc.), wherein the plurality of leads are connected to the plurality of wires in one-to-one correspondence. For example, the first lead 371 is connected to the first fanout wire 311, the second lead 372 is connected to the second fanout wire 312, the third lead 373 is connected to the third fanout wire 313, and so forth. The plurality of leads are connected between the plurality of COFs 60 and the plurality of wires. For example, the plurality of leads are integrally formed with the plurality of wires.

In some embodiments, a width of each wire is equal to a width of a lead connected to the each wire. For example, the width of the first fanout wire 311 is equal to a width of the first lead 371, the width of the second fanout wire 312 is equal to the width of the second lead 372, and the width of the third fanout wire 313 is equal to a width of the third lead 373, and so forth.

In some embodiments, widths of different leads may or may not be equal.

In some embodiments, widths of the plurality of leads are equal, and the widths of the plurality of leads are all equal to a width of a wire in the middle position of the fanout wire portion.

It is to be noted that, the “width equality” described in the embodiment of the present disclosure comprises but is not limited to absolute equality, but there may be a certain error, that is, the above-described “width equality” may comprise a circumstance that the widths are approximately equal within a certain error range.

In other embodiments, a width of each wire is not equal to a width of a lead connected to the each wire. For example, the width of each wire is greater than the width of the lead connected to the each wire.

In other embodiments of the present disclosure, a display panel is provided. As shown in FIG. 3, the display panel comprises a fanout area 30. The fanout area 30 comprises a plurality of fanout wire portions 300. Each fanout wire portion 300 comprises a plurality of wires and a plurality of leads. The plurality of wires comprise a part of wires arranged along a direction from a middle position 303 of the fanout wire portion to a first boundary position 301 of the fanout wire portion. A difference between a width of a wire close to the first boundary position in the part of wires and a width of a lead connected to the wire close to the first boundary position is greater than or equal to a difference between a width of a wire away from the first boundary position in the part of wires and a width of a lead connected to the wire away from the first boundary position.

For example, a difference between the width of the first fanout wire 311 and the width of the first lead 371 is greater than or equal to a difference between the width of the second wire 312 and the width of the second lead 372. For another example, a difference between the width of the second fanout wire 312 and the width of the second lead 372 is greater than or equal to a difference between the width of the third wire 313 and the width of the third lead 373.

In the above-described embodiments, the closer to the first boundary position of the fanout wire portion, the greater the difference between the width of the wire and the width of the lead connected to the wire, so that a resistance difference between the fanout wires of the display panel can be reduced as much as possible and the display effect of the display panel can be improved.

In some embodiments, as shown in FIG. 3, the part of wires comprise a plurality of first wire groups 31 arranged along a direction from the middle position 303 of the fanout wire portion 300 to the first boundary position 301 of the fanout wire portion. For example, the plurality of first wire groups 31 comprise: a first sub-wire group 310 close to the first boundary position 301 of the fanout wire portion and a second sub-wire group 320 close to the middle position 303 of the fanout wire portion. A difference between a width of a wire of the first sub-wire group 310 and a width of a lead connected to the wire of the first sub-wire group is greater than or equal to a difference between a width of a wire of the second sub-wire group 320 and a width of a lead connected to the wire of the second sub-wire group 320. For example, a difference between the width of the first fanout wire 311 and the width of the first lead 371 is greater than or equal to a difference between the width of the third fanout wire 313 and the width of the third lead 373. This may reduce a resistance difference between the fanout wires of the display panel as much as possible, improve the uniformity of the resistance of the fanout wires of the display panel and improve the display effect of the display panel.

In some embodiments, as shown in FIG. 3, the plurality of wires comprise: a first fanout wire 311 located at the first boundary position 301 of the fanout wire portion, a second fanout wire 312 adjacent to the first fanout wire 311, and a third fanout wire 313 on a side of the second fanout wire 312 away from the first fanout wire 311 and adjacent to the second fanout wire 312. For example, the width of the first fanout wire 311 is greater than the width of the second fanout wire 312, and the width of the second fanout wire 312 is equal to the width of the third fanout wire 313. This may reduce a resistance difference between the fanout wires of the display panel as much as possible and improve the display effect of the display panel.

For example, a difference between the width of the first fanout wire 311 and the width of the second fanout wire 312 is 0.01 microns. For example, a difference between the width of the second fanout wire 312 and the width of the third fanout wire 313 is 0.

FIG. 4 is a schematic view showing a display panel according to another embodiment of the present disclosure.

As shown in FIG. 4, the fanout area 30 comprises a plurality of fanout wire portions 300. Each fanout wire portion 300 comprises a plurality of wires. The plurality of wires comprise a plurality of first wire groups 31 arranged along a direction from a middle position 303 of the fanout wire portion to a first boundary position 301 of the fanout wire portion.

The plurality of first wire groups 31 comprise: a first sub-wire group 310 close to the first boundary position 301 of the fanout wire portion and a second sub-wire group 320′ close to the middle position 303 of the fanout wire portion.

In some embodiments, as shown in FIG. 4, the plurality of first wire groups 31 further comprise a third sub-wire group 330 between the first sub-wire group 310 and the second sub-wire group 320′. A difference between widths of adjacent wires in the third sub-wire group 330 is less than a difference between widths of the adjacent wires in the first sub-wire group 310, and the difference between the widths of the adjacent wires in the third sub-wire group 330 is greater than a difference between widths of adjacent wires in the second sub-wire group 320′.

For example, as shown in FIG. 4, the first sub-wire group 310 comprises a first fanout wire 311 and a second fanout wire 312, the second sub-wire group 320′ comprises a fifth fanout wire 315 and a sixth fanout wire 316, and the third sub-wire group 330 comprises a third fanout wire 313 and a fourth fanout wire 314.

For example, as described previously, the difference between the widths of adjacent wires in the first sub-wire group 310 is the difference between the width W1 of the first fanout wire 311 and the width W2 of the second fanout wire 312. For example, the difference between the widths of adjacent wires in the second sub-wire group 320′ is the difference between the width W5 of the fifth fanout wire 315 and the width W6 of the sixth fanout wire 316. For example, the difference between the widths of adjacent wires in the third sub-wire group 330 is the difference between the width W3 of the third fanout wire 313 and the width W4 of the fourth fanout wire 314.

In the above-described embodiments, the difference between the width W3 of the third fanout wire 313 and the width W4 of the fourth fanout wire 314 is less than the difference between the width W1 of the first fanout wire 311 and the width W2 of the second fanout wire 312, and greater than the difference between the width W5 of the fifth fanout wire 315 and the width W6 of the sixth fanout wire 316.

For example, the difference between the widths of adjacent wires in the first sub-wire group 310 ranges from 6.25 nanometers to 10.42 nanometers. For another example, the difference between the widths of adjacent wires in the second sub-wire group 320′ ranges from 4.17 nanometers to 8.33 nanometers. For another example, the difference between the widths of adjacent wires in the third sub-wire group 330 ranges from 5.21 nanometers to 9.38 nanometers.

So far, a display panel according to another embodiment of the present disclosure is provided. In the display panel, the plurality of first wire groups of each fanout wire portion comprise a first sub-wire group, a second sub-wire group and a third sub-wire group, wherein the difference between the widths of adjacent wires in the third sub-wire group is less than the difference between the widths of adjacent wires in the first sub-wire group, and greater than the difference between the widths of adjacent wires in the second sub-wire group. This may further reduce a resistance difference between the fanout wires of the display panel and improve the display effect of the display panel.

In the above description, the first sub-wire group, the second sub-wire group and the third sub-wire group are a plurality of sub-wire groups on one side at the middle position of the fanout wire portion, and the above-described solution may at least reduce a resistance difference between some fanout wires of the fanout wire portion.

It is to be noted that, although it is described above that the plurality of first wire groups of each fanout wire portion comprise two or three sub-wire groups, the scope of the present disclosure is not limited thereto. For example, the plurality of first wire groups of each fanout wire portion may comprise more sub-wire groups.

In some embodiments, as shown in FIG. 4, the plurality of wires at each fanout wire portion 300 further comprise a plurality of second wire groups 32 arranged along a direction from the middle position 303 of the each fanout wire portion to a second boundary position 302 of the each fanout wire portion. The second boundary position 302 is opposite to the first boundary position 301. In the plurality of fanout wire portions, a width of a wire closest to the second boundary position of at least one fanout wire portion in the at least one fanout wire portion is greater than a width of a wire closest to the second boundary position of another fanout wire portion in the another fanout wire portion. This may reduce a resistance difference between a part of fanout wires.

In some embodiments, in the plurality of second wire groups 32 of each fanout wire portion, a difference between widths of adjacent wires in a second wire group close to the second boundary position 302 of the each fanout wire portion is greater than a difference between widths of adjacent wires in a second wire group away from the second boundary position 302 of the each fanout wire portion (for example, a second wire group close to the middle position 303). This may reduce a resistance difference between another part of fanout wires of the fanout wire portion.

For example, as shown in FIG. 4, the plurality of second wire groups 32 comprise: a fourth sub-wire group 340 close to the second boundary position 302 of the each fanout wire portion and a fifth sub-wire group 350 close to the middle position 303 of the each fanout wire portion. A difference between widths of adjacent wires in the fourth sub-wire group 340 is greater than a difference between widths of adjacent wires in the fifth sub-wire group 350. This may reduce a resistance difference between the fanout wires of the fanout wire portion.

In some embodiments, as shown in FIG. 4, the plurality of second wire groups 32 further comprise a sixth sub-wire group 360 between the fourth sub-wire group 340 and the fifth sub-wire group 350. A difference between widths of adjacent wires in the sixth sub-wire group 360 is less than the difference between the widths of adjacent wires in the fourth sub-wire group 340, and the difference between the widths of adjacent wires in the sixth sub-wire group 360 is greater than the difference between the widths of adjacent wires in the fifth sub-wire group 350. This can further reduce a resistance difference between the fanout wires of the display panel and improve the display effect of the display panel.

In the above description, the fourth sub-wire group, the fifth sub-wire group and the sixth sub-wire group are a plurality of sub-wire groups on the other side at the middle position of the fanout wire portion, and the above-described solution may at least reduce a resistance difference between another part of fanout wires of the fanout wire portion.

It is to be noted that, although it is described above that the plurality of second wire groups of each fanout wire portion comprise two or three sub-wire groups, the scope of the present disclosure is not limited thereto. For example, the plurality of second wire groups of each fanout wire portion may comprise more sub-wire groups.

In some embodiments, in each fanout wire portion, the plurality of first wire groups and the plurality of second wire groups may be symmetrically arranged or asymmetrically arranged.

It is to be noted that, the fanout wire 317 located at the middle position 303 of the fanout wire portion may belong to the second sub-wire group 320′ or to the fifth sub-wire group 350, or may be used as a sub-wire group alone.

In some embodiments, for a wire in each second wire group, the closer to the second boundary position 302 of the fanout wire portion, the greater a width of the wire. For example, in the sixth sub-wire group 360, the closer the fanout wire is to the second boundary position 302, the greater the width of the fanout wire is. This can reduce a resistance difference between the wires in each second wire group.

In some embodiments, a difference between widths of adjacent wires in the each second wire group is equal.

For example, the above-described difference is a value other than 0, so that widths of a plurality of wires in each second wire group increase uniformly along a direction from the middle position of the fanout wire portion to the second boundary position of the fanout wire portion. In this way, for the second wire group comprising fanout wires with a relatively large length difference, a resistance difference between the fanout wires in the second wire group can be made relatively small.

For another example, the above-described difference is 0, so that widths of a plurality of wires in each second wire group are equal. In this way, for the second wire group comprising fanout wires with a relatively small length difference, a resistance difference between the fanout wires in the second wire group can be made relatively small.

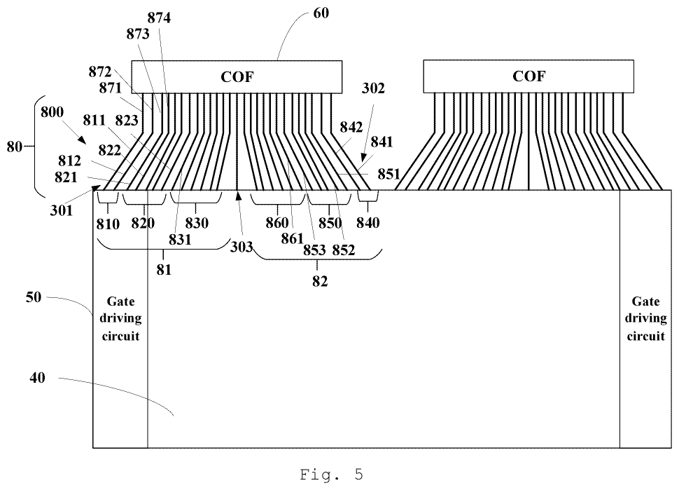

FIG. 5 is a schematic view showing a display panel according to another embodiment of the present disclosure.

As shown in FIG. 5, the display panel comprises a fanout area 80. The fanout area 80 comprises a plurality of fanout wire portions 800. Here, each fanout wire portion is a group of fanout wires electrically connected to a same COF 60. Each fanout wire portion 800 comprises a plurality of wires. The plurality of wires comprise a plurality of first wire groups 81 arranged along a direction from the middle position 303 of the each fanout wire portion to the first boundary position 301 of the each fanout wire portion. In the plurality of fanout wire portions, a width of a wire closest to the first boundary position of at least one fanout wire portion in the at least one fanout wire portion is greater than a width of a wire closest to the first boundary position of another fanout wire portion in the another fanout wire portion.

In some embodiments, a difference between widths of adjacent wires in each first wire group of the plurality of first wire groups 81 of each fanout wire portion is equal, and the difference is not 0.

For example, as shown in FIG. 5, the plurality of first wire groups 81 comprise first wire groups 810, 820 and 830, wherein the first wire group 810 comprises a first fanout wire 811 and a second fanout wire 812, another first wire group 820 comprises a third fanout wire 821, a fourth fanout wire 822 and a fifth fanout wire 823, and a further first wire group 830 comprises a sixth fanout wire 831 and the like. Here, each first wire group only exemplarily shows or marks some fanout wires, and the scope of the present disclosure is not limited thereto.

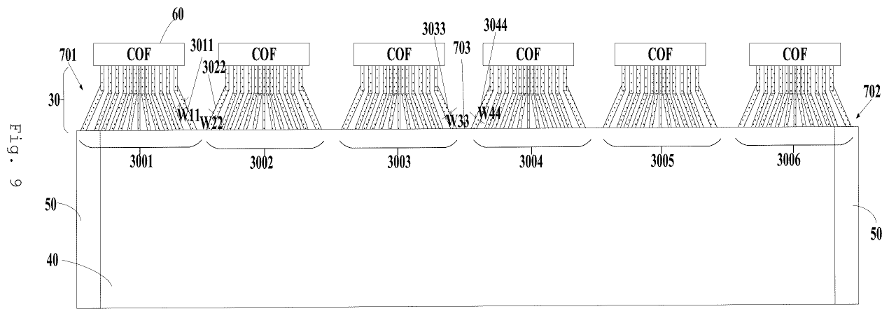

FIG. 8 is a schematic view showing a fanout wire and a lead of a fanout wire portion according to an embodiment of the present disclosure. FIG. 8 shows a third fanout wire 821, a fourth fanout wire 822, a third lead 873 (to be described later) and a fourth lead 874 (to be described later), and other fanout wires and leads which are also similar will not be shown one by one here. In addition, FIG. 8 also shows a width W821 of the third fanout wire 821 and a width W822 of the fourth fanout wire 822, and widths of other fanout wires which are similar will not be shown here. Furthermore, FIG. 8 also shows a distance between adjacent leads, for example, a distance do between the third lead 873 and the fourth lead 874, and distances between other adjacent leads which are similar will not be shown here one by one.

As described previously, a difference between widths of adjacent wires in each first wire group of the plurality of first wire groups 81 of each fanout wire portion is equal, and the difference is not 0. For example, a difference between a width of the first fanout wire 811 and a width of the second fanout wire 822 is equal to a difference between a width of the third fanout wire 821 and a width of the fourth fanout wire 822. Of course, it is also equal to a difference between widths of adjacent wires in other first wire groups, which will not be described one by one here. For example, the difference between the widths of adjacent wires in each first wire group is 0.01 microns. Of course, the scope of the disclosure is not limited thereto.

Furthermore, a width of a fanout wire in the each first wire group is positively correlated with a distance from the fanout wire to the middle position 303 of the each fanout wire portion. That is, in each first wire group, the greater the distance from the fanout wire to the middle position 303 of the fanout wire portion, the greater the width of the fanout wire. This can reduce a resistance difference between the fanout wires of the display panel as much as possible and improve the display effect of the display panel.

In some embodiments, the plurality of first wire groups comprise: a first sub-wire group close to the first boundary position 301 of the each fanout wire portion and a second sub-wire group adjacent to the first sub-wire group and close to the middle position 303 of the each fanout wire portion, wherein a width of the fanout wire closest to the second sub-wire group in the first sub-wire group is equal to a width of the fanout wire closest to the first sub-wire group in the second sub-wire group.

For example, description will be made by taking the first wire group 810 which is the first sub-wire group and the first wire group 820 which is the second sub-wire group as an example. The first sub-wire group 810 is close to the first boundary position 301 of the fanout wire portion, and the second sub-wire group 820 is adjacent to the first sub-wire group 810 and close to the middle position 303 of the fanout wire portion. A width of the fanout wire 812 closest to the second sub-wire group 820 in the first sub-wire group 810 is equal to a width of the fanout wire 821 closest to the first sub-wire group 810 in the second sub-wire group 820.

For another example, description will be made by taking the first wire group 820 which is the first sub-wire group and the first wire group 830 which is the second sub-wire group as an example. The first sub-wire group 820 is close to the first boundary position 301 of the fanout wire portion, and the second sub-wire group 830 is adjacent to the first sub-wire group 820 and close to the middle position 303 of the fanout wire portion. A width of the fanout wire 823 closest to the second sub-wire group 830 in the first sub-wire group 820 is equal to a width of the fanout wire 831 closest to the first sub-wire group 820 in the second sub-wire group 830.

So far, a display panel according to some embodiments of the present disclosure is described. In the display panel, the difference between the widths of adjacent wires in each first wire group of the plurality of first wire groups of each fanout wire portion is equal, and the width of the fanout wire in each first wire group is positively correlated with the distance from the fanout wire to the middle position of the each fanout wire portion. The plurality of first wire groups comprise: a first sub-wire group close to the first boundary position of the each fanout wire portion and a second sub-wire group adjacent to the first sub-wire group and close to the middle position of the each fanout wire portion, wherein the width of the fanout wire closest to the second sub-wire group in the first sub-wire group is equal to the width of the fanout wire closest to the first sub-wire group in the second sub-wire group. In this way, a resistance difference between at least part of fanout wires of the fanout wire portion of the display panel can be reduced as much as possible, and the uniformity of the resistance of the at least part of the fanout wires can be improved, thereby improving the display effect of the display panel.

In some embodiments, as shown in FIG. 5, the plurality of wires further comprise a plurality of second wire groups 82 arranged along a direction from the middle position 303 of each fanout wire portion to a second boundary position 302 of the each fanout wire portion. The second boundary position 302 is opposite to the first boundary position 301.

A difference between widths of adjacent wires in each second wire group of the plurality of second wire groups 82 of the each fanout wire portion is equal, and the difference is not 0.

For example, as shown in FIG. 5, the plurality of second wire groups 82 comprise second wire groups 840, 850 and 860, wherein the second wire group 840 comprises a seventh fanout wire 841 and an eighth fanout wire 842, another second wire group 850 comprises a ninth fanout wire 851, a tenth fanout wire 852 and an eleventh fanout wire 853, and a further second wire group 860 comprises a twelfth fanout wire 861 and the like. Here, each second wire group only exemplarily shows or marks a part of fanout wires, and the scope of the present disclosure is not limited thereto.

As described previously, the difference between the widths of adjacent wires in each second wire group of the plurality of second wire groups 82 of each fanout wire portion is equal, and the difference is not 0. For example, a difference between a width of the seventh fanout wire 841 and a width of the eighth fanout wire 842 is equal to a difference between a width of the ninth fanout wire 851 and a width of the tenth fanout wire 852. Of course, it is also equal to a difference between widths of adjacent wires in other second wire groups, which will not be described one by one here. For example, the difference between the widths of adjacent wires in each second wire group is 0.01 microns. Of course, the scope of the disclosure is not limited thereto.

Furthermore, a width of a fanout wire in each second wire group is positively correlated with a distance from the fanout wire to the middle position 303 of the each fanout wire portion. That is, in each second wire group, the greater the distance from the fanout wire to the middle position 303 of the fanout wire portion, the greater the width of the fanout wire. This can reduce a resistance difference between the fanout wires of the display panel as much as possible, improve the uniformity of the resistance of the fanout wires of the display panel and improve the display effect of the display panel.

In some embodiments, the plurality of second wire groups 82 comprise: a fourth sub-wire group close to the second boundary position 302 of the each fanout wire portion and a fifth sub-wire group adjacent to the fourth sub-wire group and close to the middle position 303 of the each fanout wire portion, wherein a width of the fanout wire closest to the fifth sub-wire group in the fourth sub-wire group is equal to a width of the fanout wire closest to the fourth sub-wire group in the fifth sub-wire group.

For example, description will be made by taking the second wire group 840 which is the fourth sub-wire group and the second wire group 850 which is the fifth sub-wire group as an example. The fourth sub-wire group 840 is close to the second boundary position 302 of the fanout wire portion, and the fifth sub-wire group 850 is adjacent to the fourth sub-wire group 840 and close to the middle position 303 of the fanout wire portion. A width of the fanout wire 842 closest to the fifth sub-wire group 850 in the fourth sub-wire group 840 is equal to a width of the fanout wire 851 closest to the fourth sub-wire group 840 in the fifth sub-wire group 850.

For another example, description will be made by taking the second wire group 850 which is the fourth sub-wire group, and the second wire group 860 which is the fifth sub-wire group as an example. The fourth sub-wire group 850 is close to the second boundary position 302 of the fanout wire portion, the fifth sub-wire group 860 is adjacent to the fourth sub-wire group 850 and close to the middle position 303 of the fanout wire portion, and a width of the fanout wire 853 closest to the fifth sub-wire group 860 in the fourth sub-wire group 850 is equal to a width of the fanout wire 861 closest to the fourth sub-wire group 850 in the fifth sub-wire group 860.

The above-described embodiments may reduce a resistance difference between at least part of fanout wires of the fanout wire portion of the display panel as much as possible and improve the display effect of the display panel.

In some embodiments, as shown in FIG. 5, in each fanout wire portion of at least one fanout wire portion, the plurality of second wire groups and the plurality of first wire groups are symmetrically arranged according to the width of the fanout wire. In this way, a resistance difference between the fanout wires of the entire fanout wire portion can be reduced as much as possible, the uniformity of the resistance of the fanout wires of the entire fanout wire portion can be improved and the display effect of the display panel can be improved.

In some embodiments, as shown in FIG. 5, each fanout wire portion further comprises a plurality of leads, wherein the plurality of leads are electrically connected to the plurality of wires in one-to-one correspondence. For example, a first lead 871, a second lead 872, a third lead 873 and a fourth lead 874 are shown in FIG. 5, and so forth. The first lead 871 is electrically connected to the first fanout wire 811, the second lead 872 is electrically connected to the second fanout wire 812, the third lead 873 is electrically connected to the third fanout wire 821, the fourth lead 874 is electrically connected to the fourth fanout wire 822, and so forth. The plurality of leads are also electrically connected to the COF 60.

Widths of the plurality of leads are equal. For example, the widths of the first lead 871, the second lead 872, the third lead 873 and the fourth lead 874 are all equal.

A width of each lead is less than or equal to a width of a wire electrically connected to the each lead. For example, the width of the first lead 871 is less than or equal to the width of the first fanout wire 811, the width of the second lead 872 is less than or equal to the width of the second fanout wire 812, and so forth.

A distance between adjacent leads in the plurality of leads is equal. For example, a distance between the first lead 871 and the second lead 872 is equal to a distance between the second lead 872 and the third lead 873, and so forth.

In the above-described embodiments, the electrical connection between the fanout wires and the COF is achieved through the plurality of leads.

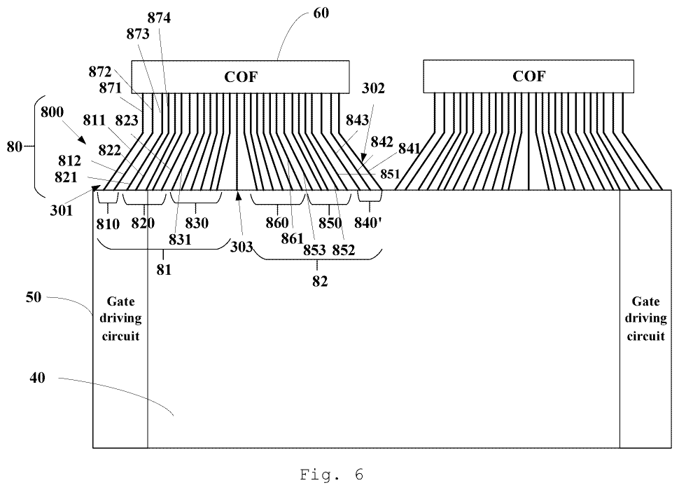

FIG. 6 is a schematic view showing a display panel according to another embodiment of the present disclosure.

The display panel shown in FIG. 6 is similar to the display panel shown in FIG. 5, so that description will not be made for those that are the same as or similar to the parts of the display panel shown in FIG. 5. Compared with the display panel shown in FIG. 5, the display panel shown in FIG. 6 is different in that: in each fanout wire portion, a plurality of second wire groups 82 and a plurality of first wire groups 81 are asymmetrically arranged according to the width of the fanout wire. For example, as shown in FIG. 6, in the plurality of first wire groups 81, the first wire group 810 comprises two fanout wires 811 and 812; and in the plurality of second wire groups 82, the second wire group 840′ comprises three fanout wires 841, 842 and 843.

In some embodiments, in each fanout wire portion of at least one fanout wire portion, a width of the fanout wire closest to the second boundary position 302 is greater than a width of the fanout wire closest to the first boundary position 301. For example, a width of the fanout wire 841 closest to the second boundary position 302 is greater than a width of the fanout wire 811 closest to the first boundary position 301.

In some embodiments, as shown in FIG. 8, a width of the fanout wire 811 is equal to a width of the fanout wire 842, and a width of the fanout wire 812 is equal to a width of the fanout wire 843.

It is to be noted that, the fanout wire portion 800 shown in FIG. 5 and the fanout wire portion 800 shown in FIG. 6 may be in the fanout area of a same display panel, and may also be in fanout areas of different display panels, so that the scope of the present disclosure is not limited thereto.

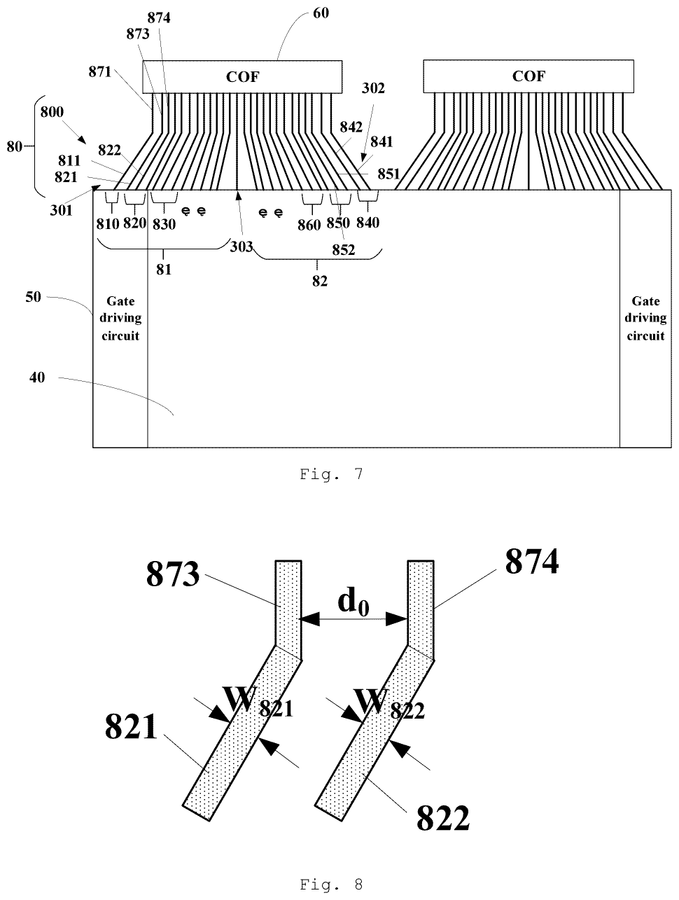

FIG. 7 is a schematic view showing a display panel according to another embodiment of the present disclosure.

In some embodiments, as shown in FIG. 7, in the plurality of first wire groups of each fanout wire portion, a number of a fanout wire of each first wire group of other first wire groups (for example, other first wire groups 820 and 830, and the like) than a first wire group 810 closest to the first boundary position 301 is equal. For example, the number of the fanout wire in the first wire group 810 is 1, but the number of the fanout wire in the first wire group 820 is 3, and the number of the fanout wire in the first wire group 830 is also 3, and so forth. In the plurality of second wire groups of each fanout wire portion, a number of a fanout wire of each second wire group of other second wire groups (for example, other second wire groups 850 and 860, and the like) than a second wire group 840 closest to the second boundary position 302 is equal. For example, the number of the fanout wire of the second wire group 840 is 2, but the number of the fanout wire of the second wire group 850 is 3, and the number of the fanout wire of the second wire group 860 is also 3, and so forth. Moreover, the number of the fanout wire of the each second wire group of the other second wire groups is equal to the number of the fanout wire of the each first wire group of the other first wire groups.

In addition, similarly as previously, the width of the fanout wire in each first wire group is positively correlated with the distance from the fanout wire in the each first wire group to the middle position of the each fanout wire portion, and the width of the fanout wire in each second wire group is positively correlated with the distance from the fanout wire in the each second wire group to the middle position of the each fanout wire portion. This can reduce a resistance difference between the fanout wires of the entire fanout wire portion as much as possible, improve the uniformity of the resistance of the fanout wires of the entire fanout wire portion and improve the display effect of the display panel.

In some embodiments, a range of the number of the fanout wire of each first wire group of the other first wire groups and a range of the number of the fanout wire of each second wire group of the other second wire groups are both 3 to 5. That is, the number of the fanout wire of each of the other first wire groups ranges from 3 to 5, and the number of the fanout wire of each of the other second wire groups ranges from 3 to 5. This grouping is conductive to reduce a resistance difference between the fanout wires of the entire fanout wire portion, and improve the uniformity of the resistance of the fanout wires of the entire fanout wire portion.

In some embodiments, as shown in FIG. 7, in each of the at least one fanout wire portion, a width of a fanout wire 811 closest to the first boundary position 301 is greater than a width of a fanout wire 841 closest to the second boundary position 302.

In some embodiments, a width of the lead in the fanout wire portion as shown in FIG. 7 is greater than a width of the lead in the fanout wire portion as shown in FIG. 5 or 6, and a distance between adjacent leads in the fanout wire portion as shown in FIG. 7 is less than a distance between adjacent leads in the fanout wire portion as shown in FIG. 5 or 6.

In other embodiments, in the fanout area of the display panel, the width of the lead in one fanout wire portion is greater than the width of the lead in another fanout wire portion, and the distance between adjacent leads in the one fanout wire portion is less than the distance between adjacent leads in the another fanout wire portion. In this way, it is possible to design the width and distance of the leads of different fanout wire portions as necessary.

The inventors of the present disclosure have also found that, in the related art, due to the influence of process fluctuation, adjacent fanout wire portions of the display panel might result in a large resistance difference between two most adjacent fanout wires in the adjacent fanout wire portions, which may lead to the problem of poor display. For example, in the related art, the resistance difference between the two most adjacent fanout wires in the adjacent fanout wire portions may reach 5Ω (Ohm) to 59Ω.

In view of this, the embodiment of the present disclosure also provides a display panel according to another embodiment, so as to reduce a resistance difference between the two most adjacent fanout wires in the adjacent fanout wire portions. The display panel according to other embodiments of the present disclosure is described in detail below in conjunction with FIG. 9.

FIG. 9 is a schematic view showing a display panel according to another embodiment of the present disclosure.

For example, as shown in FIG. 9, the fanout area 30 comprises a plurality of fanout wire portions (for example, a first fanout wire portion 3001, a second fanout wire portion 3002, a third fanout wire portion 3003, a fourth fanout wire portion 3004, a fifth fanout wire portion 3005 and a sixth fanout wire portion 3006). As shown in FIG. 9, in the plurality of fanout wire portions, a difference between widths of adjacent fanout wires of adjacent fanout wire portions close to a boundary position (for example, a first boundary position 701 or a second boundary position 702) of the fanout area is greater than or equal to a difference between widths of adjacent fanout wires of adjacent fanout wire portions close to a middle position 703 of the fanout area.

Next, a detailed description is made by taking the boundary position of the fanout area as the first boundary position 701 as an example.

For example, as shown in FIG. 9, the adjacent fanout wire portions close to the boundary position of the fanout area comprise: a first fanout wire portion 3001 close to the boundary position 701 of the fanout area 30, and a second fanout wire portion 3002 on a side of the first fanout wire portion 3001 away from the boundary position of the fanout area and adjacent to the first fanout wire portion 3001. The first fanout wire portion 3001 comprises a first wire 3011, the first wire 3011 being a wire closest to the second fanout wire portion 3002 in the first fanout wire portion 3001. The second fanout wire portion 3002 comprises a second wire 3022, the second wire 3022 being a wire closest to the first fanout wire portion 3001 in the second fanout wire portion 3002. The first wire 3011 and the second wire 3022 are the adjacent wires of the adjacent fanout wire portions close to the boundary position 701 of the fanout area 30.

For example, as shown in FIG. 9, the adjacent fanout wire portions close to the middle position of the fanout area comprise: a third fanout wire portion 3003 and a fourth fanout wire portion 3004 which are close to the middle position 703 of the fanout area. For example, the third fanout wire portion 3003 is on one side of the middle position 703, and the fourth fanout wire portion 3004 is on the other side of the middle position 703. The third fanout wire portion 3003 comprises a third wire 3033, the third wire 3033 being a wire closest to the fourth fanout wire portion 3004 in the third fanout wire portion 3003. The fourth fanout wire portion 3004 comprises a fourth wire 3044, the fourth wire 3044 being a wire closest to the third fanout wire portion 3003 in the fourth fanout wire portion 3004. The third wire 3033 and the fourth wire 3044 are the adjacent wires of the adjacent fanout wire portions close to the middle position 703 of the fanout area.

In some embodiments, a difference between a width W11 of the first wire 3011 and a width W22 of the second wire 3022 is greater than or equal to a difference between a width W33 of the third wire 3033 and a width W44 of the fourth wire 3044.

In the above-described embodiments, in the plurality of fanout wire portions in the fanout area, the difference between the widths of adjacent wires of adjacent fanout wire portions close to the boundary position of the fanout area is greater than or equal to the difference between the widths of adjacent wires of adjacent fanout wire portions close to the middle position of the fanout area. This can reduce a resistance difference between two most adjacent fanout wires in adjacent fanout wire portions, so as to improve the display effect of the display panel.

For example, the above-described display panel may make the resistance of various fanout wires at adjacent positions in adjacent fanout wire portions as uniform as possible.

It is to be noted that, although description has been made above by taking the first boundary position 701 as an example, the scope of the present disclosure is not limited thereto. For example, a difference between widths of adjacent wires of adjacent fanout wire portions close to the second boundary position 702 of the fanout area is greater than the difference between the widths of adjacent wires of adjacent fanout wire portions close to the middle position 703 of the fanout area. Here, the adjacent fanout wire portions and adjacent wires close to the second boundary position 702 of the fanout area are similar to the adjacent fanout wire portions and adjacent wires close to the first boundary position of the fanout area, which will not be described in detail here.

In some embodiments, the difference between the widths of the adjacent wires of the adjacent fanout wire portions ranges from 0.05 microns to 0.2 microns. For example, the difference between the width W11 of the first wire 3011 and the width W22 of the second wire 3022 ranges from 0.1 microns to 0.2 microns. For another example, the difference between the width W33 of the third wire 3033 and the width W44 of the fourth wire 3044 ranges from 0.05 microns to 0.1 microns.

In some embodiments, the width of the fanout wire at the boundary position of the fanout wire portion is 4.0 microns to 4.1 microns. For example, the widths of two fanout wires at two boundary positions of the fanout wire portion are both 4.0 microns. For another example, the width of the fanout wire at one boundary position of the fanout wire portion is 4.0 microns, and the width of the fanout wire at another boundary position of the fanout wire portion is 4.1 microns. The width of the fanout wire at the boundary position of the fanout wire portion may be designed according to actual conditions.

In some embodiments, a distance between adjacent wires in each fanout wire portion is 6.5 microns. In some embodiments, the width of the fanout wire at the boundary position of each fanout wire portion is 3.9 microns.

During an actual design process of the fanout area, a ratio of line width to line distance might be affected by the number of frames and masks. For example, in a first process, a common electrode layer (for example, an ITO (Indium tin oxide) layer) and a gate layer are formed by using two masks respectively, and a source/drain layer and an active layer are formed by using two masks respectively. In single-layer wiring formed by using the first process, a minimum width of some wires may be 3.5 microns, and a minimum line distance may be 4.8 microns. For another example, in a second process, a common electrode layer and a gate layer are formed together by using one mask, and a source/drain layer and an active layer are formed together by using one mask. In single-layer wiring formed by the second process, the line width of a wire in the same layer as the gate layer is a sum of a design value of the line width and a tail width of the common electrode layer, the line width of a wire in the same layer as the source/drain layer is a sum of a design value of the line width and a tail width of the active layer, the line distance of the wire in the same layer as the gate layer is the sum of the design value of the line distance and two times the tail width of the common electrode layer, and the line distance of the wire in the same layer as the source/drain layer is the sum of the design value of the line distance and two times the tail width of the active layer.

In some embodiments of the present disclosure, a display apparatus is also provided, the display apparatus comprising the display panel as described previously, for example, the display panel shown in FIG. 3, FIG. 4, FIG. 5, FIG. 6, FIG. 7 or FIG. 9. For example, the display apparatus may be any product or member having a display function, such as a mobile phone, a tablet computer, a television, a display, a notebook computer, a digital photo frame, a navigator, or the like.

Hereto, various embodiments of the present disclosure have been described in detail. Some details well known in the art are not described in order to avoid obscuring the concept of the present disclosure. According to the above description, those skilled in the art would fully understand how to implement the technical solutions disclosed here.

Although some specific embodiments of the present disclosure have been described in detail by way of examples, those skilled in the art should understand that the above examples are only for an illustrative purpose, rather than limiting the scope of the present disclosure. It should be understood by those skilled in the art that modifications to the above embodiments and equivalent replacements to some technical features may be made without departing from the scope and spirit of the present disclosure. The scope of the present disclosure is defined by the appended claims.

1. A display panel, comprising:
a fanout area comprising a plurality of fanout wire portions, wherein each fanout wire portion of the plurality of fanout wire portions comprises a plurality of wires, the plurality of wires comprising a plurality of first wire groups arranged along a direction from a middle position of the each fanout wire portion to a first boundary position of the each fanout wire portion, and in the plurality of fanout wire portions, a width of a wire closest to the first boundary position of at least one fanout wire portion in the at least one fanout wire portion being greater than a width of a wire closest to the first boundary position of another fanout wire portion in the another fanout wire portion.

2. The display panel according to claim 1, wherein in the plurality of first wire groups of the each fanout wire portion, a difference between widths of adjacent wires in a first wire group close to the first boundary position of the each fanout wire portion is greater than a difference between widths of adjacent wires in a first wire group away from the first boundary position of the each fanout wire portion.

3. The display panel according to claim 2, wherein the plurality of first wire groups comprise:
a first sub-wire group close to the first boundary position of the each fanout wire portion and a second sub-wire group close to the middle position of the each fanout wire portion, wherein a difference between widths of adjacent wires in the first sub-wire group is greater than a difference between widths of adjacent wires in the second sub-wire group; and
a third sub-wire group between the first sub-wire group and the second sub-wire group, wherein a difference between widths of adjacent wires in the third sub-wire group is less than the difference between the widths of the adjacent wires in the first sub-wire group, and the difference between the widths of the adjacent wires in the third sub-wire group is greater than the difference between the widths of the adjacent wires in the second sub-wire group.

4. (canceled)

5. (canceled)

6. (canceled)

7. The display panel according to claim 1, wherein for a wire in each first wire group of the plurality of first wire groups, the closer to the first boundary position of the each fanout wire portion, the greater a width of the wire.

8. (canceled)

9. The display panel according to claim 1, wherein:
the each fanout wire portion further comprises a plurality of leads, wherein the plurality of leads are connected to the plurality of wires in one-to-one correspondence, and a width of each wire of the plurality of wires is equal to a width of a lead connected with the each wire; or
the each fanout wire portion further comprises a plurality of leads, wherein the plurality of leads are connected to the plurality of wires in one-to-one correspondence, widths of the plurality of leads are equal, and the widths of the plurality of leads are all equal to a width of a wire at the middle position of the each fanout wire portion.

10. (canceled)

11. The display panel according to claim 1, wherein:
the plurality of wires further comprise a plurality of second wire groups arranged along a direction from the middle position of the each fanout wire portion to a second boundary position of the each fanout wire portion, wherein the second boundary position is opposite to the first boundary position, and in the plurality of fanout wire portions, a width of a wire closest to the second boundary position of at least one fanout wire portion in the at least one fanout wire portion is greater than a width of a wire closest to the second boundary position of another fanout wire portion in the another fanout wire portion.

12. The display panel according to claim 11, wherein in the plurality of second wire groups of the each fanout wire portion, a difference between widths of adjacent wires in a second wire group close to the second boundary position of the each fanout wire portion is greater than a difference between widths of adjacent wires in a second wire group away from the second boundary position of the each fanout wire portion.

13. The display panel according to claim 12, wherein the plurality of second wire groups comprise:
a fourth sub-wire group close to the second boundary position of the each fanout wire portion and a fifth sub-wire group close to the middle position of the each fanout wire portion, wherein a difference between widths of adjacent wires in the fourth sub-wire group is greater than a difference between widths of adjacent wires in the fifth sub-wire group; and
a sixth sub-wire group between the fourth sub-wire group and the fifth sub-wire group, wherein a difference between widths of adjacent wires in the sixth sub-wire group is less than the difference between the widths of the adjacent wires in the fourth sub-wire group, and the difference between the widths of the adjacent wires in the sixth sub-wire group is greater than the difference between the widths of the adjacent wires in the fifth sub-wire group.

14. (canceled)

15. The display panel according to claim 11, wherein for a wire in each second wire group of the plurality of second wire groups, the closer to the second boundary position of the each fanout wire portion, the greater a width of the wire.

16. (canceled)

17. The display panel according to claim 1, wherein:
a difference between widths of adjacent wires in each first wire group of the plurality of first wire groups of the each fanout wire portion is equal, the difference is not 0, and a width of a fanout wire in the each first wire group is positively correlated with a distance from the fanout wire to the middle position of the each fanout wire portion; and
the plurality of first wire groups comprise: a first sub-wire group close to the first boundary position of the each fanout wire portion and a second sub-wire group adjacent to the first sub-wire group and close to the middle position of the each fanout wire portion, wherein a width of the fanout wire closest to the second sub-wire group in the first sub-wire group is equal to a width of the fanout wire closest to the first sub-wire group in the second sub-wire group.

18. The display panel according to claim 17, wherein:
the plurality of wires further comprise a plurality of second wire groups arranged along a direction from the middle position of the each fanout wire portion to a second boundary position of the each fanout wire portion, wherein the second boundary position is opposite to the first boundary position;
a difference between widths of adjacent wires in each second wire group of the plurality of second wire groups of the each fanout wire portion is equal, the difference is not 0, and a width of a fanout wire in the each second wire group is positively correlated with a distance from the fanout wire to the middle position of the each fanout wire portion; and
the plurality of second wire groups comprise a fourth sub-wire group close to the second boundary position of the each fanout wire portion and a fifth sub-wire group adjacent to the fourth sub-wire group and close to the middle position of the each fanout wire portion, wherein a width of the fanout wire closest to the fifth sub-wire group in the fourth sub-wire group is equal to a width of the fanout wire closest to the fourth sub-wire group in the fifth sub-wire group.

19. The display panel according to claim 18, wherein:
in each fanout wire portion of the at least one fanout wire portion, the plurality of second wire groups and the plurality of first wire groups are symmetrically arranged according to the width of the fanout wire; or
in each fanout wire portion of the at least one fanout wire portion, a width of the fanout wire closest to the second boundary position is greater than a width of the fanout wire closest to the first boundary position; or
in the plurality of first wire groups of the each fanout wire portion, a number of a fanout wire of each of other first wire groups than a first wire group closest to the first boundary position is equal, and in the plurality of second wire groups of the each fanout wire portion, a number of a fanout wire of each of other second wire groups than a second wire group closest to the second boundary position is equal, and the number of the fanout wire of the each of the other second wire groups is equal to the number of the fanout wire of the each of the other first wire groups.

20. (canceled)

21. The display panel according to claim 1, wherein the each fanout wire portion further comprises a plurality of leads, wherein the plurality of leads are electrically connected to the plurality of wires in one-to-one correspondence, widths of the plurality of leads are equal, a width of each lead of the plurality of leads is less than or equal to a width of a wire electrically connected to the each lead, and a distance between adjacent leads in the plurality of leads is equal.

22. (canceled)

23. (canceled)

24. The display panel according to claim 18, wherein in each of the at least one fanout wire portion, a width of a fanout wire closest to the first boundary position is greater than a width of a fanout wire closest to the second boundary position.

25. The display panel according to claim 18, wherein:
in the plurality of first wire groups of the each fanout wire portion, a number of a fanout wire of each of other first wire groups than a first wire group closest to the first boundary position ranges from 3 to 5, and
in the plurality of second wire groups of each fanout wire portion, a number of a fanout wire of each other second wire groups than a second wire group closest to the second boundary position ranges from 3 to 5.

26. The display panel according to claim 1, wherein in the plurality of fanout wire portions, a difference between widths of adjacent wires of adjacent fanout wire portions close to a boundary position of the fanout area is greater than or equal to a difference between widths of adjacent wires of adjacent fanout wire portions close to a middle position of the fanout area.

27. (canceled)

28. (canceled)

29. The display panel according to claim 1, further comprising:
a display area; and
a gate driving circuit electrically connected to the display area, wherein the display area and the gate driving circuit are electrically connected to the plurality of fanout wire portions.

30. (canceled)

31. A display panel, comprising:
a fanout area comprising a plurality of fanout wire portions, wherein each fanout wire portion of the plurality of fanout wire portions comprises a plurality of wires and a plurality of leads, wherein the plurality of wires comprise a part of wires arranged along a direction from a middle position of each fanout wire portion to a first boundary position of each fanout wire portion, and a difference between a width of a wire close to the first boundary position in the part of wires and a width of a lead connected to the wire close to the first boundary position is greater than or equal to a difference between a width of a wire away from the first boundary position in the part of wires and a width of a lead connected to the wire away from the first boundary position.

32. The display panel according to claim 31, wherein:
the part of wires comprise a plurality of first wire groups arranged along the direction from the middle position of each fanout wire portion to the first boundary position of each fanout wire portion, wherein the plurality of first wire groups comprise: a first sub-wire group close to the first boundary position of each fanout wire portion and a second sub-wire group close to the middle position of each fanout wire portion, wherein a difference between a width of a wire of the first sub-wire group and a width of a lead connected to the wire of the first sub-wire group is greater than or equal to a difference between a width of a wire of the second sub-wire group and a width of a lead connected to the wire of the second sub-wire group; or
the plurality of wires comprise: a first fanout wire at the first boundary position of each fanout wire portion, a second fanout wire adjacent to the first fanout wire, and a third fanout wire on a side of the second fanout wire away from the first fanout wire and adjacent to the second fanout wire, wherein a width of the first fanout wire is greater than a width of the second fanout wire, and the width of the second fanout wire is equal to a width of the third fanout wire.

33. (canceled)

34. (canceled)

35. A display apparatus, comprising: the display panel according to claim 1.
